(19) United States
(12) Patent Application Publication
(10) Pub. No.: US 2026/0282932 A1
(43) Pub. Date: Sep. 17, 2026

(54) SEMICONDUCTOR PACKAGE AND A METHOD FOR FORMING THE SAME

(71) Applicant: JCET STATS ChipPAC Korea Limited, Incheon (KR)

(72) Inventors: WonSang RHEE, Incheon (KR); KyoungHee PARK, Seoul (KR); SeongHwan PARK, Incheon (KR)

(21) Appl. No.: 19/565,532

(22) Filed: Mar. 13, 2026

(30) Foreign Application Priority Data
Mar. 14, 2025 (CN) 202510300573.4

(51) Int. Cl. H10W 42/20; H10W 70/05; H10W 74/01; H10W 76/01; H10W 76/17

(52) U.S. Cl. CPC H10W 42/276; H10W 70/096; H10W 74/014; H10W 76/01; H10W 76/17

(57) ABSTRACT

A semiconductor package and a method for forming the same are provided. The semiconductor package comprises: a substrate; at least one electronic component mounted on a front surface of the substrate; a metal cap attached on the front surface of the substrate, wherein the metal cap comprises: a cavity accommodating the at least one electronic component; and a supporting component at a bottom surface of the metal cap which creates a gap between the metal cap and the substrate; a mold cap formed within the cavity to encapsulate the at least one electronic component; and a shielding layer formed at least on a lateral surface of the substrate and a lateral surface of the metal cap, wherein the shielding layer is electrically connected with the metal cap.

### TECHNICAL FIELD

The present application generally relates to semiconductor technologies, and more particularly, to a semiconductor package and a method for forming a semiconductor package.

### BACKGROUND OF THE INVENTION

The semiconductor industry is constantly faced with complex integration challenges as consumers want their electronics to be smaller, faster and have higher performance with more and more functionalities packed into a single device. For a semiconductor package, a shielding layer may be formed at an outer surface of the semiconductor package to protect underlying components, for example, electronic components and substrates, from electromagnetic interference. During a conventional fabrication process of multiple semiconductor packages, the shielding layer is typically applied to each individual semiconductor package after their singulation from a package substrate strip, covering both lateral and top surfaces of the semiconductor package. This unit-by-unit deposition approach may significantly increase manufacturing costs, particularly in mass production of semiconductor packages.

Therefore, a need exists for further improvements for a method to form a semiconductor package having a shielding layer.

### SUMMARY OF THE INVENTION

An objective of the present application is to provide a method to form a semiconductor package having a shielding layer with a reduced cost.

According to an aspect of the present application, a method for making a semiconductor package is disclosed. The method comprises: providing a substrate strip comprising a plurality of substrate units and a plurality of saw regions each located between two adjacent substrate units; mounting at least one electronic component on a front surface of each substrate unit; attaching a plurality of metal caps onto the substrate strip to cover the front surfaces of the plurality of substrate units respectively but expose the plurality of saw regions, wherein each of the plurality of metal caps defines a cavity to accommodate the at least one electronic component on the corresponding substrate unit and has a supporting component at a bottom surface of the metal cap to create a gap between the metal cap and the corresponding substrate unit; applying a molding material on the substrate strip to form a molding layer encapsulating the metal caps and the substrate strip, wherein the molding material flows into the cavities of the plurality of metal caps through the respective gaps to form respective mold caps; removing the saw regions of the substrate strip and a portion of the molding layer on the saw regions to form a groove and a mold linkage between each two adjacent substrate units, wherein the groove exposes lateral surfaces of the two substrate units adjacent thereto and a portion of lateral surfaces of two metal caps on the two adjacent substrate units; forming a shielding layer at least on the lateral surfaces of the substrate units and the exposed lateral surfaces of the metal caps; and removing the mold linkages to separate the plurality of substrate units into a plurality of substrates, such that each of the plurality of substrates, together with the at least one electronic component mounted thereon, one of the mold caps encapsulating the at least one electronic component and one of the metal caps covering the substrate, form a semiconductor package.

According to another aspect of the present application, a semiconductor package is provided. The semiconductor package comprises: a substrate; at least one electronic component mounted on a front surface of the substrate; a metal cap attached on the front surface of the substrate, wherein the metal cap comprises: a cavity accommodating the at least one electronic component; and a supporting component at a bottom surface of the metal cap which creates a gap between the metal cap and the substrate; a mold cap formed within the cavity to encapsulate the at least one electronic component; and a shielding layer formed at least on a lateral surface of the substrate and a lateral surface of the metal cap, wherein the shielding layer is electrically connected with the metal cap.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1K illustrate a method for forming a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, in a semiconductor package, a shielding layer may be formed to protect underlying components, for example, electronic components and a substrate within the semiconductor package, from electromagnetic interferences. During a conventional fabrication process of multiple semiconductor packages, a package substrate strip is first singulated into individual units to expose their lateral surfaces. Afterwards, a shielding layer is applied to each individual semiconductor package, covering both lateral and top surfaces of the semiconductor package, which may significantly increase manufacturing costs.

To address this issue, a new method for forming a semiconductor package is provided. The method introduces metal caps onto a substrate strip to cover underlying electronic component(s) on each substrate unit of the substrate strip which occupies a portion of the substrate strip. Then a molding layer is formed to encapsulate the metal caps and the electronic components mounted on the substrate strip. Next, a portion of the molding layer between each two adjacent substrate units is removed to form a groove there, exposing lateral surfaces of the substrate units and the metal caps while remaining connection of the two adjacent substrate units and structures thereon by a mold linkage therebetween. Next, a shielding layer is formed on the exposed lateral surfaces of the substrate units and the metal caps. In this way, the shielding layer can be formed on the desired surface of each substrate unit and the structure thereon simultaneously at a strip level rather than at a unit level. Afterwards, the mold linkages are then removed to singulate the substrate units from the substrate strip, thereby forming individual semiconductor packages. This method can enhance production efficiency and significantly reduce manufacturing costs.

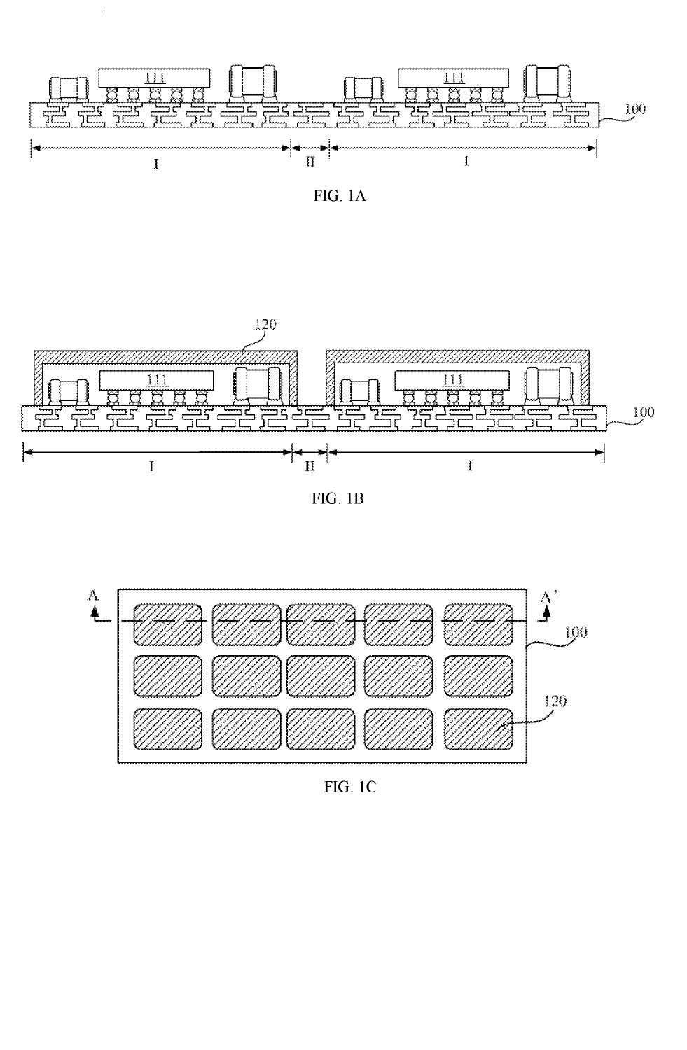

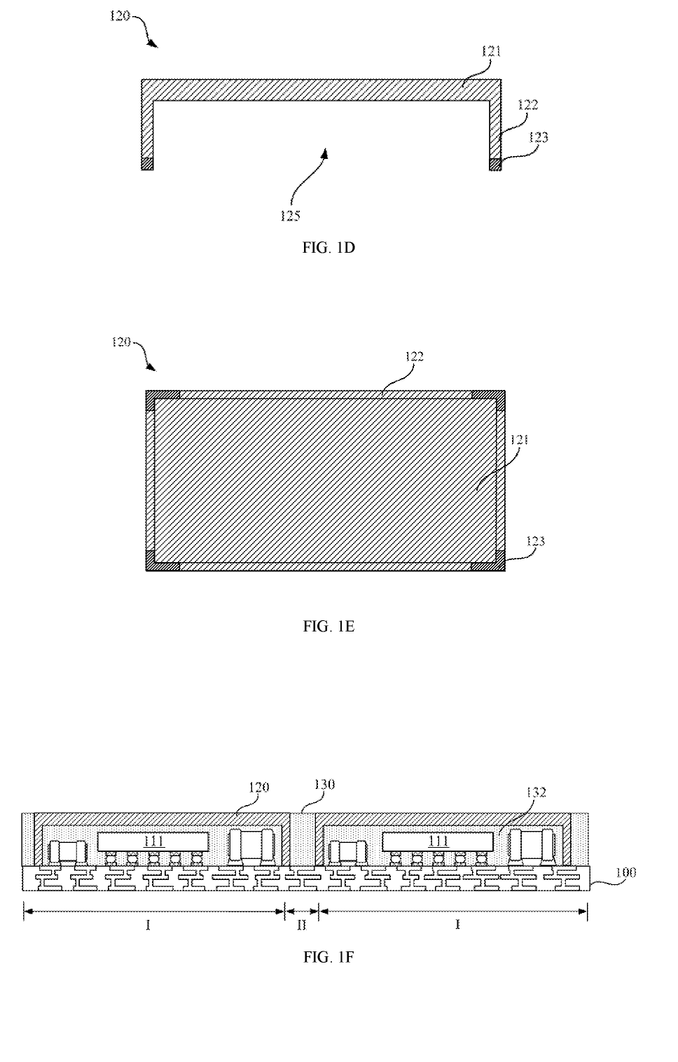

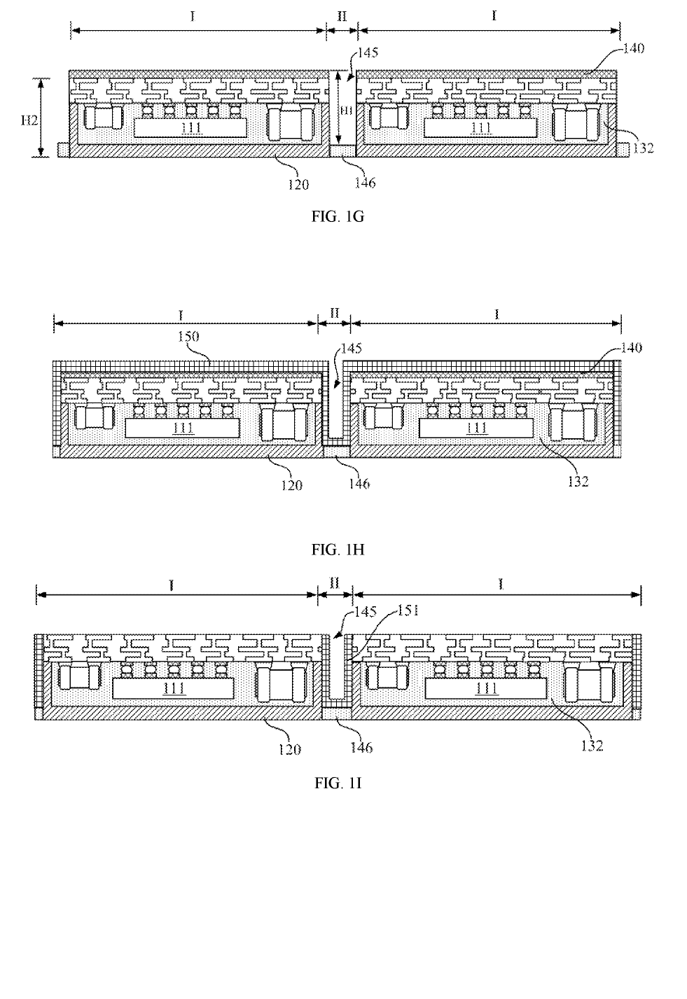

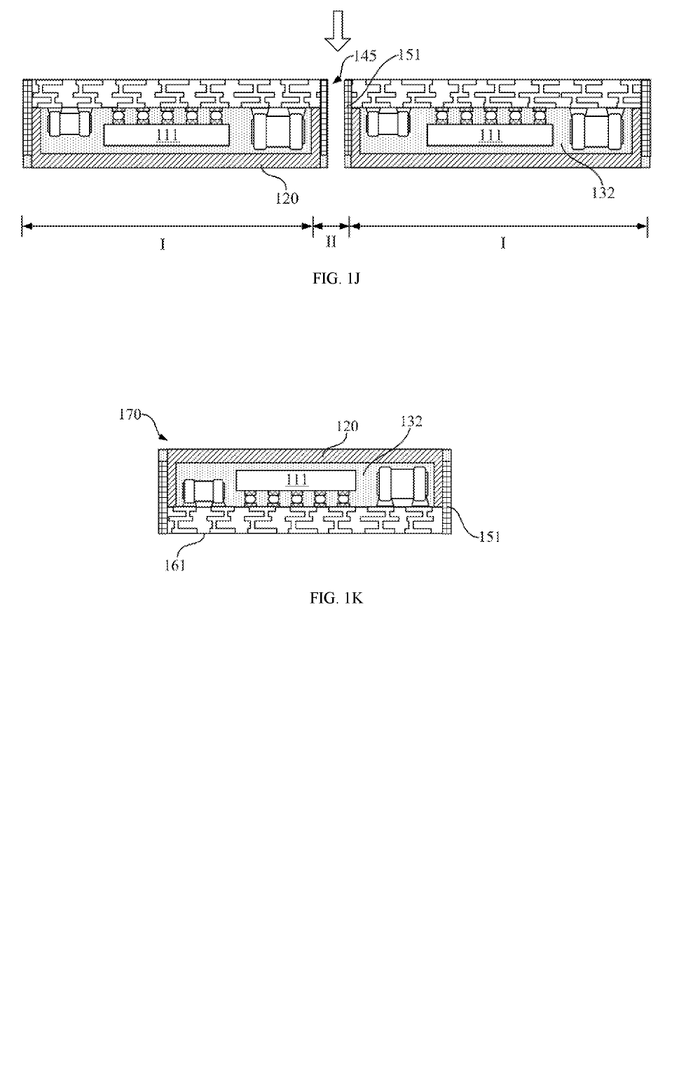

FIGS. 1A to 1K illustrate a method for forming a semiconductor package according to an embodiment of the present application. The semiconductor package formed using the method is shown in FIG. 1K.

As shown in FIG. 1A, a substrate strip 100 is provided. The substrate strip 100 includes a plurality of substrate units I which may have the same layout and overall structure. In some other embodiments, the substrate units I may be different in layout and overall structure, which can also be processed using the method of the present application. After a subsequent packaging process which will be detailed below, the substrate units I can be singulated from the substrate strip 100 to form a plurality of pieces each being an individual semiconductor package. It can be appreciated that the following processes are described with reference to two substrate units I of the substrate strip 100 as an example, and the same or similar processes can be implemented to a portion or all the substrate units I of the substrate strip 100.

The substrate strip 100 includes a front surface facing upward in the direction shown in FIG. 1A, and a back surface opposite to the front surface. In some embodiments, the substrate strip 100 may be made of silicon or other semiconductor materials, or may include a printed circuit board (PCB), a carrier substrate, a ceramic substrate, a laminate interposer, a strip interposer, a leadframe, or other suitable substrates. In some examples, the substrate strip 100 may include redistribution layers or structures having one or more dielectric layers and one or more conductive layers between and through the dielectric layers. Thus, various components and other structures on either one surface or both surfaces of the substrate strip 100 may be electrically coupled with each other. In some embodiments, a first set of conductive pads can be formed on the front surface and/or the back surface of the substrate strip 100 for mounting the various components thereon. It can be appreciated that the first set of conductive pads may be exposed portions of interconnect wires formed within the substrate strip 100.

The substrate strip 100 also includes a plurality of saw regions II, each of which is located between two adjacent substrate units I, thus connecting the plurality of substrate units I as the substrate strip 100. The saw regions II may be dummy zones without functional modules, which may be designed for singulation in a subsequent process. It can be appreciated that both the saw regions II and the substrate units I can be formed in situ within the substrate strip 100.

Still referring to FIG. 1A, at least one electronic component 111 is attached onto the front surface of each of the substrate units I via solder bumps or in other suitable manners, thus forming electrical connection between the interconnect wires within the substrate strip 100 and the at least one electronic component 111. To be more specific, each of the at least one electronic component 111 may include a second set of conductive pads on its back surface. Each of the second set of conductive pads is aligned with one of the first set of conductive pads, and connected thereto via a solder bump. In some embodiments, the electronic component(s) 111 may be semiconductor chip(s) or smaller semiconductor package(s). It can be appreciated that more electronic components 111 may be mounted onto the front surface of each of the substrate units I. The structures, layouts, and types of the electronic components mounted on the various substrate units I may be identical or different from one another. In addition, no electronic component is mounted onto the saw regions II to avoid impacting the singulation of the substrate strip 100.

Next, as shown in FIGS. 1B and 1C, a plurality of metal caps 120 are attached onto the substrate strip 100. To be more specific, FIG. 1C illustrates a top view of the substrate strip 100 and the metal caps 120 mounted thereon, and FIG. 1B illustrates a cross-sectional view of the structures along line AA’ shown in FIG. 1C.

In the embodiment shown in FIGS. 1B and 1C, the metal caps 120 are attached onto front surfaces of the substrate units I respectively. The saw regions II of the substrate strip 100 are exposed from the metal caps 120. In particular, as shown in FIG. 1C, the substrate units I and the respective metal caps 120 attached thereon may be arranged in an array configuration having multiple columns and rows, with the saw regions II occupying interstitial grid-like spaces between each two adjacent substrate units I. In some embodiments, the metal caps 120 may be attached onto the substrate units I via adhesives, which may ensure that the metal caps 120 can be firmly fixed onto the substrate units I even if some subsequent processes are applied to the substrate strip 100. Preferably, the metal caps 120 can have the same height.

FIG. 1D illustrates an exemplary structure of one of the metal caps 120 in FIGS. 1B and 1E illustrates a bottom view of the metal cap 120 in FIG. 1D. As shown in FIGS. 1D and 1E, the metal cap includes a top plate 121 and a side wall 122 extending downward from a periphery of the top plate 121. The top plate 121 and the side wall 122 together define a cavity 125 of the metal cap 120 to accommodate the at least one electronic component 111 on the corresponding substrate unit I. In some embodiments, a gap exists between a bottom surface of the top plate 121 and top surface(s) of the electronic component(s) 111. The gap may allow a molding material to flow into the cavity 125 in a subsequent molding process, which facilitates sufficient encapsulation of the electronic component(s) 111 and avoids undesired contact between the metal cap 120 and the electronic component(s) 111. As shown in FIG. 1E, the top plate 121 has a rectangular layout, which may be similar to a shape of the substrate unit I. In some other embodiments, the top plate 121 may have other shaped layouts, such as a circle, a hexagon or an octagon, as long as the electronic component(s) 111 on the respective substrate unit I can be accommodated within the cavity 125 of the metal cap 120. In addition, a supporting component 123 is arranged at a bottom surface of the side wall 122. The supporting component 123 may be in direct contact with the respective substrate unit I when the metal cap 120 is attached onto the substrate unit I. As shown in FIG. 1E, in the embodiment, the supporting component 123 includes four supporting footprints arranged at a bottom surface of the side wall 122 at four corners of the rectangular top plate 121. In some other embodiments, more or less supporting footprints can be included within the metal cap 120. Also, the supporting footprints may be placed at positions other than the corners of the top plate 121, for example, at midpoints of the bottom edges of the metal cap 120. In this embodiment, the four supporting footprints may have a height which slightly elevates the side wall 122 and the top plate 121, such that the gap is created between the side wall 122 and the corresponding substrate unit I. In the embodiment, the gap includes four sections each located between two adjacent footprints. In this way, when a molding material is applied on the substrate strip 100 in the subsequent molding process, the molding material may flow from the outside of the metal caps 120 into the cavities 125 of the metal caps 120 through the respective gaps to encapsulate the electronic components 111. In some other embodiments, the side wall 122 of the metal cap 120 may include slits, openings or other suitable structures which similarly facilitate the flow of the molding material into the cavity 125 of the metal cap 120. It can be appreciated that in some preferred embodiments two or more slits or openings are formed in each of the metal caps 120 to improve flow of the molding material into the metal cap 120.

In some embodiments, the top plate 121, the side wall 122 and the supporting component 123 may be integrally formed as the metal cap 120 in the form of a single piece. In some other embodiments, the supporting component 123 may be a separate piece or separate pieces which can be assembled to the side wall 122 before the metal cap 120 is attached onto the substrate unit I. It should be noted that the supporting components 123 of the metal caps 120 are omitted in FIG. 1B for simplicity.

In some embodiments, each metal cap 120 may include silver, copper, aluminum, nickel or their combinations. In some preferred embodiments, each metal cap 120 may include metal with a surface coating, for example, an aluminum core with a nickel coating, especially for the supporting component 123.

Still referring to FIG. 1C, the metal caps 120 may be separate pieces and can be attached to the respective substrate units I individually. In some other embodiments, the metal caps 120 can be preloaded into an assembly frame to fix them at specific positions within the frame. Then all the metal caps 120 can be attached onto the substrate strip 100 simultaneously by using the frame, thereby significantly increasing efficiency of the attaching process of the metal caps 120. In some alternative embodiments, each pair of adjacent metal caps 120 may be connected together through a linkage, such that all the metal caps 120 can be attached onto the substrate strip 100 in a batch manner. In some preferred embodiments, the linkages may be removed after the metal caps 120 are mounted onto the substrate strip 100. In some embodiments, alignment marks, such as alignment slots may be formed on the substrate strip 100 to receive the metal caps 120 respectively, which may guarantee precise alignment between the substrate units I and the respective metal caps 120.

Next, as shown in FIG. 1F, after the metal caps 120 are attached onto the substrate strip 100, a molding material is applied onto the substrate strip 100 to form a molding layer 130 that encapsulates the metal caps 120 and the substrate strip 100. In some embodiments, the molding layer 130 may be formed using an injection molding process or a compression molding process. In some other embodiments, the molding layer 130 may be formed using paste printing, transfer molding, liquid encapsulant molding, vacuum lamination, spin coating, or any other suitable process.

To be more specific, the formation of the molding layer 130 may include a melting process that melts the molding material. The melted molding material then covers the front surfaces of the saw regions II to form encapsulation thereon. At the same time, the molding material also flows into the cavities of the metal caps 120 through the respective gaps between the supporting components 123 and the side walls 122 of the respective metal caps 120. In some other embodiments, the side wall 122 of each metal cap 120 may further include slits or openings. The melted molding material may also flow into the cavities through the respective slits or openings, thereby enhancing the efficiency of the molding process. In this way, each of the cavities is filled with a portion of the molding material, thereby encapsulating the electronic component(s) 111 accommodated within the cavity. Afterwards, a curing process may be implemented to solidify the melted molding material. Both the melting process and the curing process can be conducted by applying a heating process to the entire substrate strip. As such, the melted molding material may be solidified into mold caps 132 encapsulating the respective electronic components 111. The mold caps 132 and the encapsulation on the saw regions II together form the entire molding layer 130.

In some embodiments, a portion of the molding layer 130 may also be formed on the top surfaces of the metal caps 120. Thus, a grinding process, for example, a chemical mechanical polishing (CMP) process may be implemented to remove the portion of the molding layer 130 above the metal caps 120 to expose the top surfaces of the metal caps 120. At the same time, a portion of the molding layer 130 on the saw regions II may also be grinded, such that the entire package strip may have a flat top surface which generally expose the top surfaces of the metal caps 120.

Next, as shown in FIG. 1G, the substrate strip 100 with the molding layer 130 thereon may be flipped over, with the back surface of the substrate strip 100 facing upward in the direction shown in FIG. 1G. For example, the substrate strip 100 may be placed on a carrier platform (not shown). Next, a mask layer 140 is applied onto the back surface of the substrate strip 100. The mask layer 140 may be used to protect the substrate strip 100 when grooves are formed within the saw regions II of the substrate strip 100, which will be elaborated below. The mask layer 140 may be a releasable mask, which may be removed easily after a subsequent deposition process. For example, the mask layer 140 may be made from a photosensitive material which may exhibit different adhesiveness or strength before and after exposure to light radiation, or may be made from an adhesive tape, providing temporary protection for the substrate units I during subsequent processes.

Next, a plurality of mask openings may be formed through the mask layer 140, with each masking opening exposing one of the saw regions II. It can be appreciated that the saw regions II may be connected with each other as that shown in FIG. 1C, then the mask openings can also be connected with each other in a similar manner. Next, the saw regions II and a portion of the molding layer 130 on the saw regions II may be removed through respective masking openings of the mask layer 140, forming a groove 145 between each two adjacent substrate units I and mold caps 132. This process may be implemented using etching, milling, pinching or their combinations. In some preferred embodiments, the process of removing the saw regions II and the portion of the molding layer 130 thereon can be conducted through laser cutting. In particular, each groove 145 exposes lateral surfaces of the two substrate units I adjacent thereto and a portion of lateral surfaces of the two metal caps 120 on the two adjacent substrate units I. Generally, materials of the metal caps 120 and the molding layer 130 are different. Therefore, control of the groove width is inherently facilitated as the lateral surfaces of the metal caps 120 naturally function as a stop layer during removal of the molding layer 130 on the saw regions II.

As shown in FIG. 1G, the molding layer 130 on the saw regions II (which is removed) is not completely removed. In other words, a portion of the molding layer 130 remains below each groove 145 to form a mold linkage 146 between each two adjacent mold caps 132. Therefore, the structures on two adjacent substrate units I, i.e., the two adjacent metal caps 120 and the mold caps 132 can be interconnected with each other through the mold linkage 146 therebetween. Consequently, the substrate strip 100 can be transported and undergo subsequent processes at a strip level, thereby significantly enhancing manufacturing efficiency.

In some embodiments, each groove 145 may have a depth H1 which can not only expose at least a portion of the lateral surfaces of the two adjacent metal caps 120 but also maintain the mold linkage 146 with an adequate thickness to ensure reliable interconnection between two adjacent mold caps 132. To be more specific, a minimum thickness of the mold linkage 146 may be the same as the thickness of the top plate 121 of the metal cap 120. Also, a maximum thickness of the mold linkage 146 may be smaller than the height of the side wall 122 of the metal cap 120, such that at least a portion of the side wall 122 can be exposed for subsequent deposition of a shielding material.

Next, as shown in FIG. 1H, a shielding material 150 is deposited onto the patterned mask layer 140 and lateral surfaces of the grooves 145. In particular, the shielding material 150 may cover a front surface of the mask layer 140, the lateral surfaces of the substrate units I, the exposed lateral surfaces of the metal caps 120 and top surfaces of the mold linkages 146. In particular, the shielding material 150 may be deposited on exposed lateral surfaces of the side walls 122 and lateral surfaces of the supporting components 123, and it may also fill the respective gaps between the side walls 122 and the respective substrate units I. The shielding material 150 is generally conductive and thus electrically connected with the metal caps 120. In this way, the connected shielding material 150 and metal cap 120 can form an integral electromagnetic shielding layer for the substrate unit I and the electronic components thereunder.

Next, as shown in FIG. 1I, the patterned mask layer 140 and the shielding material 150 formed thereon may be removed together. In some embodiments, the pattern mask layer 140 may include a release mask layer 140 which can be easily removed from the substrate units I by stripping. The shielding material 150 formed on the exposed lateral surfaces of the metal caps 120 and the lateral surfaces of the substrate units I may form the shielding layer 151. It can also be appreciated that in some embodiments, the shielding material 150 may not be deposited on the surfaces of the mask layer 140 and the mold linkages 146, and the shielding material 150 may only cover the exposed lateral surfaces of the metal caps 120 and the lateral surfaces of the substrate units I to form the shielding layer 151. In some embodiments, the shielding layer 151 may include carbons, ceramics, cement, metals, conducting polymers, etc. The shielding layer 151 may or may not include the same material with the metal caps 120.

Next, as shown in FIG. 1J, the mold linkages 146 together with the shielding material 150 deposited thereon are removed, for example, by laser cutting or etching. As such, the plurality of substrate units I are separated into a plurality of substrates, and simultaneously, the mold caps 132 are also separated from each other. As such, a plurality of semiconductor packages 170 are formed. As shown in FIG. 1K, each semiconductor package 170 includes a substrate 161, at least one electronic component 111 mounted thereon, a mold cap 132 encapsulating the at least one electronic component 111, a metal cap 120 accommodating the mold cap 132, and a shielding layer 151 formed at least on a lateral surface of the substrate 161 and a lateral surface of the metal cap 120. The shielding layer 151 and the metal cap 120 are electrically connected to each other, which together cover all outer surfaces of electronic modules incorporated within the semiconductor package 170. The shielding layer 151 or the metal cap 120 may be connected to a reference voltage such as the ground (GND), thereby protecting the underlying components from electromagnetic interferences.

In the embodiment, the processes for forming the electronic packages 170, each incorporating a metal cap 120, may provide several advantages. Firstly, since the metal caps 120 and the shielding layer 151 collectively cover all outer surfaces of electronic modules incorporated within the semiconductor package 170, the shielding layer 151 can be formed on only a portion of the exposed lateral surfaces of the metal caps 120. Thus, at least a portion of the metal caps 120 do not need to be exposed for the deposition of the shielding layer 151, such that the mold linkages 146 between adjacent metal caps 120 can be preserved during the formation of the shielding layer 151. Consequently, the shielding layer 151 can be formed on the desired surface of each substrate unit I and the respective metal cap 120 attached thereon simultaneously at a strip level rather than at a unit level. This significantly increases manufacturing efficiency. Secondly, the metal caps 120 also function as electromagnetic interference shielding components. Therefore, it is more convenient to select suitable materials for the metal caps 120 to optimize electromagnetic interference shielding effect. Thirdly, the metal caps 120 include conductive materials, which may further facilitate the deposition of the conductive shielding layer 151 on their surfaces, thereby improving the quality of the formed shielding layer 151.

The discussion herein includes numerous illustrative figures that show various portions of a semiconductor package and a method for forming such semiconductor package. For illustrative clarity, such figures do not show all aspects of each example semiconductor package and method. Any of the example semiconductor package or method provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor package, the method comprising:
providing a substrate strip comprising a plurality of substrate units and a plurality of saw regions each located between two adjacent substrate units;
mounting at least one electronic component on a front surface of each substrate unit;
attaching a plurality of metal caps onto the substrate strip to cover the front surfaces of the plurality of substrate units respectively but expose the plurality of saw regions, wherein each of the plurality of metal caps defines a cavity to accommodate the at least one electronic component on the corresponding substrate unit and has a supporting component at a bottom surface of the metal cap to create a gap between the metal cap and the corresponding substrate unit;
applying a molding material on the substrate strip to form a molding layer encapsulating the metal caps and the substrate strip, wherein the molding material flows into the cavities of the plurality of metal caps through the respective gaps to form respective mold caps;
removing the saw regions of the substrate strip and a portion of the molding layer on the saw regions to form a groove and a mold linkage between each two adjacent substrate units, wherein the groove exposes lateral surfaces of the two substrate units adjacent thereto and a portion of lateral surfaces of two metal caps on the two adjacent substrate units;
forming a shielding layer at least on the lateral surfaces of the substrate units and the exposed lateral surfaces of the metal caps; and
removing the mold linkages to separate the plurality of substrate units into a plurality of substrates, such that each of the plurality of substrates, together with the at least one electronic component mounted thereon, one of the mold caps encapsulating the at least one electronic component and one of the metal caps covering the substrate, form a semiconductor package.

2. The method of claim 1, wherein each of the metal caps further comprises: a top plate and a side wall extending downward from the top plate which together define the cavity of the metal cap, and wherein the supporting component is arranged at a bottom surface of the side wall to create a gap between the side wall and the corresponding substrate unit.

3. The method of claim 2, wherein the top plate has a rectangular layout, and the supporting component comprises four supporting footprints arranged at a bottom surface of the side wall at four corners of the rectangular top plate.

4. The method of claim 2, wherein forming a shielding layer further comprises:
forming the shielding layer on exposed lateral surfaces of the side walls and lateral surfaces of the supporting component.

5. The method of claim 1, wherein each of the metal caps comprises one or more materials selected from the following group: silver, copper, aluminum and nickel.

6. The method of claim 1, wherein removing the saw regions of the substrate strip and a portion of the molding layer on the saw regions comprises:
applying a mask layer onto a back surface of the substrate strip;
forming a plurality of mask openings passing through the mask layer and each exposing one of the saw regions; and
removing the saw regions of the substrate strip and the portion of the molding layer on the saw regions through the mask layer to form the grooves and the mold linkages.

7. The method of claim 6, wherein the mask layer comprises a releasable mask.

8. The method of claim 6, wherein the step of removing the saw regions of the substrate strip and a portion of the molding layer on the saw regions is conducted through laser cutting.

9. The method of claim 1, wherein forming a shielding layer at least on the lateral surfaces of the substrate units and the exposed lateral surfaces of the metal caps comprises:
depositing a shielding material onto a patterned mask layer on back surfaces of the substrate units and lateral surfaces of the grooves to cover the lateral surfaces of the substrate units and the exposed lateral surfaces of the metal caps; and
removing the patterned mask layer and the shielding material thereon such that the shielding material on the exposed lateral surfaces of the metal caps and the lateral surfaces of the substrate units forms the shielding layer.

10. The method of claim 1, wherein after forming a molding layer encapsulating the metal caps and the substrate strip, the method further comprises:
grinding the molding layer to expose top surfaces of the metal caps.

11. A semiconductor package, comprising:
a substrate;
at least one electronic component mounted on a front surface of the substrate;
a metal cap attached on the front surface of the substrate, wherein the metal cap comprises:
a cavity accommodating the at least one electronic component; and
a supporting component at a bottom surface of the metal cap which creates a gap between the metal cap and the substrate;
a mold cap formed within the cavity to encapsulate the at least one electronic component; and
a shielding layer formed at least on a lateral surface of the substrate and a lateral surface of the metal cap, wherein the shielding layer is electrically connected with the metal cap.

12. The semiconductor package of claim 11, wherein the metal cap further comprises: a top plate and a side wall extending downward from the top plate which together define the cavity of the metal cap, and wherein the supporting component is arranged at a bottom surface of the side wall to create a gap between the side wall and the substrate.

13. The semiconductor package of claim 12, wherein the top plate has a rectangular layout, and the supporting component comprises four supporting footprints arranged at four corners of the side wall.

14. The semiconductor package of claim 11, wherein the metal cap comprises one or more materials selected from the following group: silver, copper, aluminum and nickel.
